(19) United States
(12) Patent Application Publication
(10) Pub. No.: US 2026/0058658 A1
(43) Pub. Date: Feb. 26, 2026

(54) MANIPULATION OF ANISOTROPIC G-TENSOR SPIN QUBITS VIA MAGNETIC FIELD AMPLIFICATION

(71) Applicant: INTERNATIONAL BUSINESS MACHINES CORPORATION, ARMONK, NY (US)

(72) Inventors: Gian R. von Salis, Aeugst am Albis (CH); Michele Aldeghi, Cadro (CH); Konstantinos Tsoukalas, Zurich (CH); Andreas Fuhrer Janett, Zurich (CH)

(21) Appl. No.: 18/811,726

(22) Filed: Aug. 21, 2024

(51) Int. Cl. H03K 17/92; B82Y 10/00; H10N 60/10

(52) U.S. Cl. CPC H03K 17/92; H10N 60/11; H10N 60/128; B82Y 10/00

(57) ABSTRACT

A plurality of gates on a semiconductor substrate form an array of hole spin quantum dots (qubits) in a qubit plane on the semiconductor substrate. A magnetic field producing element is configured to produce a total magnetic field. The magnetic field producing element includes a homogeneous magnetic field producing element configured to produce a homogenous magnetic field acting collectively on all the qubits in the array in a direction parallel to the qubit plane. The magnetic field producing element further includes a nonhomogeneous magnetic field producing element configured to produce a nonhomogeneous magnetic field acting individually on each qubit in the array. A frequency of each qubit depends on a direction of the total magnetic field. Manipulation circuitry is configured to perform qubit spin rotations in the array by amplifying the nonhomogeneous magnetic field in combination with anisotropic g-tensors of the qubits subjected to the total magnetic field.

### STATEMENT REGARDING FEDERALLY SPONSORED RESEARCH OR DEVELOPMENT

This application was made with government support under project NCCR SPIN, grant number is 51NF40_180604, awarded by the Swiss National Science Foundation.

### BACKGROUND

### Technical Field

The present disclosure generally relates to spin quantum computing with an array of quantum dots (qubits) in a magnetic field, and more particularly but not by way of limitation, to quantum gate operations that manipulate spin qubits to enhance gate time.

### Description of the Related Art

Quantum computation studies the application of quantum phenomena for information processing and communication. Various models of quantum computation exist, and some popular models include the concepts of qubits and quantum gates. A qubit is a generalization by a wave function that has two possible states but can be in a quantum superposition of both states. A quantum gate is a generalization of a classical logic gate. However, the quantum gate describes the transformation that one or more qubits will experience after one or more control parameters are changed for a certain time. Specifically for the type of spin qubits considered here, such control parameters may consist of voltages that are applied to electric gates that control the electric environment of the holes confined in the quantum dots. Various quantum phenomena, such as superposition and entanglement, do not have analogs in the world of classical computing and therefore may involve special structures, techniques, temperature environments, and materials.

### SUMMARY

According to one embodiment, an apparatus is provided that has a semiconductor substrate. A plurality of gates on the semiconductor substrate form an array of hole spin quantum dots (qubits) at individual qubit positions in a qubit plane on the semiconductor substrate. A magnetic field producing element is configured to produce a total magnetic field. The magnetic field producing element includes a homogeneous magnetic field producing element configured to produce a homogenous magnetic field acting collectively on all the qubits in the array in a direction parallel to the qubit plane. The magnetic field producing element further includes a nonhomogeneous magnetic field producing element configured to produce a nonhomogenous magnetic field acting individually on each qubit in the array. A frequency of each qubit depends on a direction of the total magnetic field. Manipulation circuitry is configured to perform qubit spin rotations in the array by amplifying the nonhomogeneous magnetic field in combination with anisotropic g-tensors of the qubits subjected to the total magnetic field.

According to one embodiment, a method is provided that forms a plurality of quantum gates on a semiconductor substrate to produce an array of hole spin quantum dots (qubits) at individual qubit positions in a qubit plane on the semiconductor substrate. The qubits are subjected to a magnetic field producing element configured to produce a total magnetic field. The magnetic field producing element includes a homogeneous magnetic field producing element configured to produce a homogenous magnetic field acting collectively on all the qubits in the array in a direction parallel to the qubit plane. The magnetic field producing element further includes a nonhomogeneous magnetic field producing element configured to produce a nonhomogenous magnetic field acting individually on each qubit in the array. A frequency of each qubit depends on a direction of the total magnetic field. The nonhomogeneous magnetic field is amplified at the individual qubit positions to perform qubit spin rotations in the array.

According to one embodiment, a quantum computing system having reduced manipulation time is provided. The system is configured to perform a method of forming a plurality of gates on a semiconductor substrate to produce an array of hole spin quantum dots (qubits) at individual qubit positions in a qubit plane on the semiconductor substrate. The qubits are subjected to a magnetic field producing element configured to produce a total magnetic field. The magnetic field producing element includes a homogeneous magnetic field producing element configured to produce a homogenous magnetic field acting collectively on all the qubits in the array in a direction parallel to the qubit plane. The magnetic field producing element further includes a nonhomogeneous magnetic field producing element configured to produce a nonhomogenous magnetic field acting individually on each qubit in the array. A frequency of each qubit depends on a direction of the total magnetic field. The nonhomogeneous magnetic field is amplified at the individual qubit positions to perform qubit spin rotations in the array.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 illustrates a quantum computing system having a one-dimensional array of hole spin qubits (qubits) on a semiconductor substrate, consistent with illustrative embodiments.

FIG. 2 illustrates spin precession around a magnetic field, consistent with illustrative embodiments.

FIG. 3 illustrates the anisotropic g-tensor of the qubit in FIG. 1 at a cross-section along the xy plane, consistent with illustrative embodiments.

FIG. 4a depicts one of the qubits in FIG. 1 at an initial position, consistent with illustrative embodiments.

FIG. 4b depicts the qubit in FIG. 4a after it has been displaced by application of a displacement gate voltage Va, consistent with illustrative embodiments.

FIG. 5a illustrates a one-dimensional array of qubits immersed in a nonhomogeneous magnetic field, consistent with illustrative embodiments.

FIG. 5b depicts the one-dimensional array of qubits in FIG. 5a after displacing one of the qubits relative to the nonhomogeneous magnetic field, consistent with illustrative embodiments.

FIG. 6 is a flowchart depicting a method for fast qubit manipulation, consistent with illustrative embodiments.

FIG. 7 depicts the nonhomogeneous field formed by a two-piece magnetic structure, consistent with illustrative embodiments.

FIG. 8 depicts the nonhomogeneous field formed by a magnetic structure having a pair of poles and a joint that joins the pair of poles together, consistent with illustrative embodiments.

FIG. 9 depicts a one-dimensional qubit array that includes the magnetic members in FIG. 8, consistent with illustrative embodiments.

FIG. 10 depicts a two-dimensional qubit array that includes the magnetic members in FIG. 8, consistent with illustrative embodiments.

FIG. 11a is similar to FIG. 5a in that it illustrates four qubits immersed in a nonhomogeneous magnetic field, consistent with illustrative embodiments.

FIG. 11b is similar to FIG. 11a in that it illustrates the one-dimensional array of qubits after displacing one of the qubits relative to the nonhomogeneous magnetic field, consistent with illustrative embodiments.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

Although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments can be used, and structural or logical changes can be made, without departing from the spirit and scope defined by the claims. The description of the embodiments is not limiting. In particular, elements of the embodiments described hereinafter may be combined with elements of different embodiments.

Various aspects of the present disclosure are described by narrative text, flowcharts, block diagrams of computer systems and/or block diagrams of machine logic. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

It has been found that to increase the reliability of a quantum computing system, improvements can be made to decrease qubit manipulation time, which is relevant to manipulating qubit states accurately. In one aspect, the teachings herein are based on insight that the signal fidelity of quantum gate operations on a hole spin qubit depends on the qubit manipulation time. The illustrative embodiments of the present disclosure are configured to provide substantially faster manipulation than state-of-the-art techniques. Furthermore, embodiments of the present disclosure are further based on recognition that issues unique to quantum circuits have been taken into consideration when evaluating applicability of classical signal processing techniques, and, in particular, to selecting structures and methods used for interacting efficiently with qubits.

In this detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the drawing figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a computer chip. As used herein, the term “vertical” describes an orientation that is arranged perpendicular to the first surface of a computer chip, computer chip carrier, or semiconductor body. As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments can be used, and structural or logical changes can be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

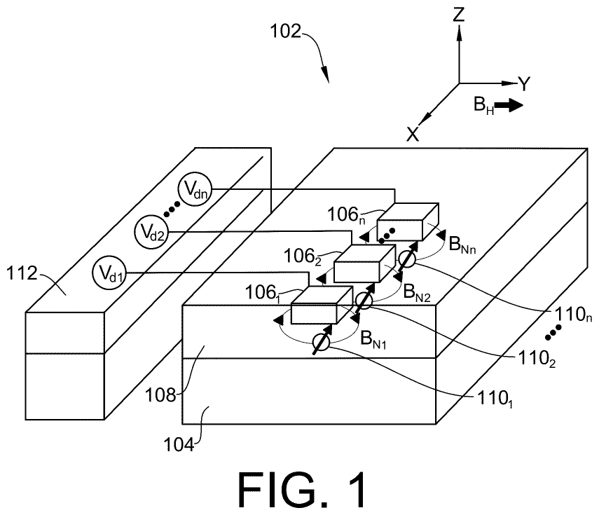

FIG. 1 illustrates a complementary metal oxide semiconductor (CMOS) integrated circuit forming a quantum computing system 102 on a support substrate 104. The support substrate 104 can be made of any suitable substrate material, such as, for example, monocrystalline Si, silicon germanium (SiGe), III-V compound semiconductor, II-VI compound semiconductor, or semiconductor-on-insulator (SOI).

In this example, the qubit computing system 102 has a plurality of gates 106 on a semiconductor substrate 108, such as a FinFET or nanowire and the like, forming an array of hole spin quantum dots (qubits) 110. The qubits 110 can be arranged in a qubit plane on the semiconductor substrate 108. In this example, the qubit plane is parallel to the xy coordinate plane. The gates 106 can be plunger gates that are used to form the qubits 110, and to control the electrical potentials of individual qubits 110. Barrier gates (not shown) can be placed in spaces between the qubits 110. The barrier gates can be used to control tunneling and thereby control exchange interactions between adjacent qubits 110.

The qubits 110 are influenced by a magnetic field producing element configured to produce a total magnetic field. The magnetic field producing element includes a homogeneous field producing element configured to produce a homogenous magnetic field B_{H}. The magnetic field producing element further includes a nonhomogeneous field producing element configured to produce a nonhomogenous magnetic field B_{N}. B_{H} acts collectively on all the qubits 110 in a direction that is parallel to the xy coordinate plane, and thus parallel to the qubit plane. B_{N} acts individually on each qubit 110 in directions that are both parallel and antiparallel to the qubit plane. In these illustrative embodiments, peripheral manipulation circuitry 112 can be configured to amplify B_{N} to manipulate qubit spin rotations in the array. In this example, the manipulation circuitry 112 is configured to amplify the nonhomogeneous field to leverage a strong anisotropy of the qubit frequency with the direction of the total magnetic field (anisotropic g-tensor). This amplifies the effect of the nonhomogeneous field on the qubit's Larmor precession axis, resulting in strongly improved qubit manipulation speed. This manipulation can be achieved by either changing the effect of the nonhomogeneous field with electric currents or by displacing the qubit position in the nonhomogeneous field.

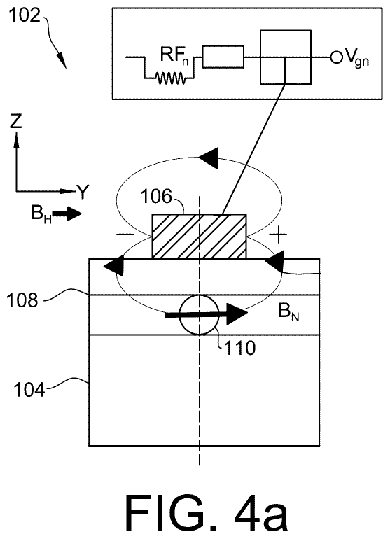

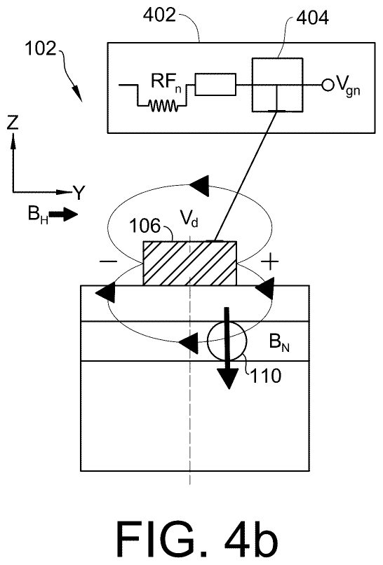

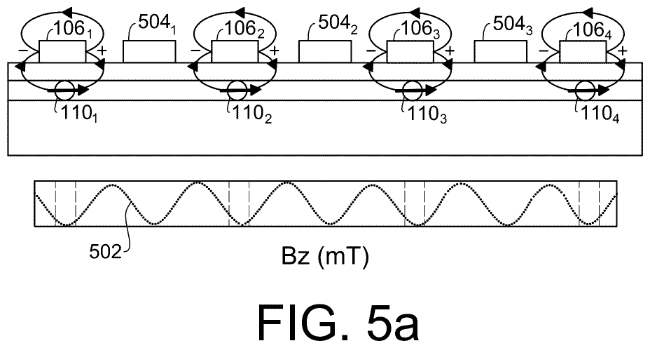

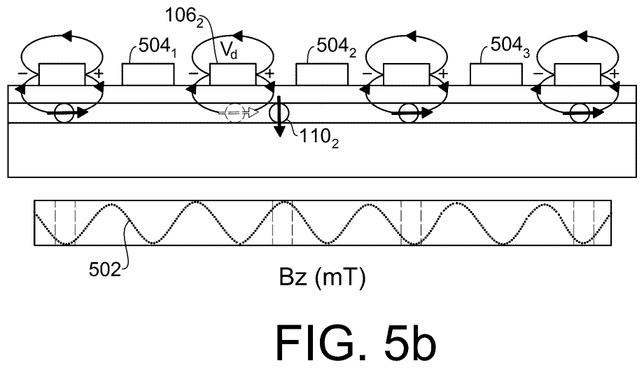

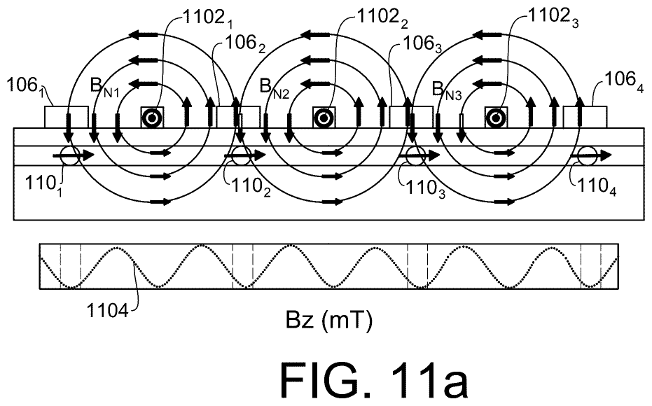

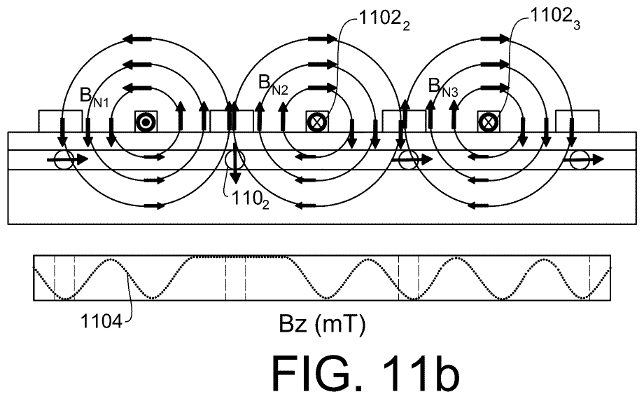

In some embodiments, such as in FIGS. 4b, 5a and 5b, a static B_{N} is provided by a magnetic structure. The magnetic structure's field acting on the qubit can be amplified by displacing the qubits 110 relative to the magnetic structure and thus, in turn, to B_{N}. In other embodiments, such as in FIGS. 11a and 11b, B_{N} can be amplified by applying alternating electric currents.

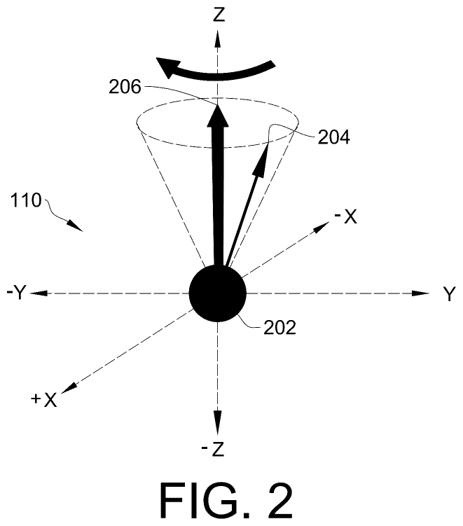

FIG. 2 illustrates one of the qubits 110 by its hole wave function 202 and its spin 204 precessing around a vertical external field B_{Z} in this example. The energy of the spin 204 can generally be computed in terms of its precession frequency:

$${hf}_{i} = {μ}_{B} gB \qquad ( Eq . 1 )$$

where h is Planck's constant, μ_{B} is the Bohr magnetron, and B is the total magnetic field vector:

$$B = ( \begin{matrix}{B}_{x} \\ {B}_{y} \\ {B}_{z}\end{matrix} ) \qquad ( Eq . 2 )$$

and g for hole spin qubits with strong spin-orbit interaction, such as in Ge/SiGe holes, can be a g-tensor:

$$g = ( \begin{matrix}{g}_{x} & & \\ & {g}_{y} & \\ & & {g}_{z}\end{matrix} ) \qquad ( Eq . 3 )$$

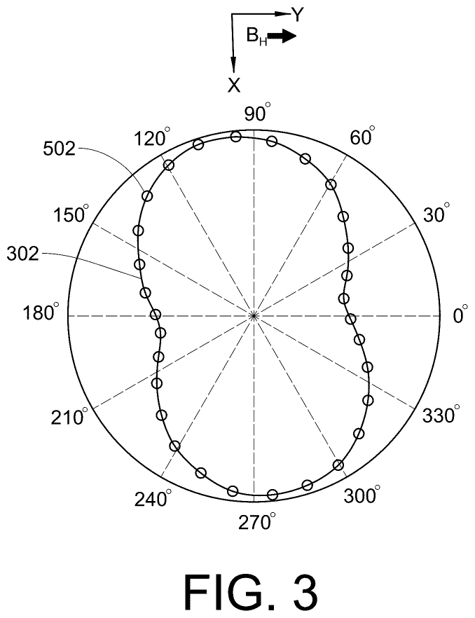

FIG. 3 plots a cross section 302 of the g-tensor as a function of the in-plane homogeneous field B_{H} that is within the xy coordinate plane in this example. We consider a g-tensor that is anisotropic, with larger values along the z-direction, and smaller in the x-y plane. Such anisotropic g tensors are typical for hole spin qubits where a strong quantization of the hole wavefunction along the z direction provides a large g_{z} component. For example, it may have its largest values near to 90 and 270 degrees, and smaller values near to 0 and 180 degrees. This characteristic can greatly amplify the out-of-plane (antiparallel) component of the magnetic stray-field B_{z} as compared to the in-plane components Bₓ, B_{y}. Amplification in this context is realized by the much stronger effect of the out-of-plane component Bz on the Larmor precession frequency of the hole spin.

Returning to FIG. 2, the Larmor vector 206 defines the precession axis. The Larmor frequency is related to the total magnetic field by the g tensor (Eq. 1). The g tensor is a material characteristic of the qubit 110 and depends for example on the electric field environment of the hole spin or on strain.

The g-tensor links the Larmor vector 206 to the total magnetic field. If the g-tensor is isotropic, then the Larmor vector is aligned to the total field. However, if the g-tensor is anisotropic, as for the hole spin qubits 110 in these illustrative embodiments, then the Larmor vector 206 and the magnetic field directions can be very different. Thus, a frequency of the hole spin qubits 110 depends on a direction of the total magnetic field. The length of the Larmor vector 206 depends linearly on the magnitude of the total magnetic field, and the angle between Larmor vector 206 and magnetic field direction depends on the magnetic field direction in a way that is determined by the g tensor. The g-tensor does not depend on the total magnetic field. However, the g-tensor can be modified by electric fields. Thus, electric field variations modify the g-tensor which, in turn, modifies the Larmor vector.

The present embodiments establish different designs to create magnetic field gradients provided by magnetic structures, aimed at tuning the local magnetic field by displacing the qubit. In this way, the magnetic field is locally tuned, such as to orient the direction of the field according to the shape of the g-tensor.

FIGS. 4a and 4b illustrate a way of manipulating the spin state by individually tuning the magnetic field for each qubit 110, consistent with illustrative embodiments. These figures more particularly illustrate the quantum computing system 102 can include multi-step and layered sequences of, for example, photolithographic and/or chemical processing steps that facilitate gradual creation of electronic-based systems, devices, components, and/or circuits in a semiconducting and/or a superconducting device (such as an integrated circuit). For instance, quantum computing system 102 can be fabricated by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

FIG. 4a illustrates the gate 106 can be a deposited and etched layer on the semiconductor substrate 108. The semiconductor substrate 108 can be formed of silicon, while it will be understood that other materials can be used as well, including, without limitation, silicon dioxide, aluminum oxide, sapphire, germanium, gallium arsenide (GaAs), an alloy of silicon and germanium, or indium phosphide (InP). Accordingly, as used herein, the term substrate includes all forms of semiconductor structures. The term “semiconductor” as used herein denotes any semiconducting material including, for example, Si, Ge, SiGe, SiC, SiGeC, and III-V compound semiconductors such as InAs, GaAs and InP. Generally, the semiconductor substrate 108 can be formed of any suitable chip/wafer material (such as a silicon substrate), and can be any suitable size, shape, and/or dimensions.

The gate 106 can be specially configured as a magnetic structure such that B_{H} is generally parallel to the magnetization of B_{N}. One way can be to deposit the gate 106 as a gate layer on the semiconductor substrate 108, such as by physical vapor deposition (PVD), chemical vapor deposition (CVD), and plasma enhanced CVD (PECVD). In other examples the gate layer can be deposited by metal-organic chemical vapor deposition (MOCVD), atomic layer deposition (ALD), plasma enhanced ALD (PEALD), low pressure CVD (LPCVD), and combinations thereof. The magnetic gate 106 can have multiple magnetic and otherwise conductive layers of different metals and/or metal compounds. In this way, the magnetic structure can be located about 500 nanometers or less from the qubit 110.

In this manner, B_{N} can include an arcuate stray magnetic field extending from one end of the (magnetic) gate 106 to an opposing end of the gate 106. The stray magnetic field forms a stray magnetic field component acting upwardly, or in a direction toward the gate 106, on the left side of the qubit 110. Similarly, the stray magnetic field forms a stray magnetic field component acting downwardly, or in a direction away from the gate 106, on the right side of the qubit 110. Between the upward and downward stray magnetic field components is a horizontal component of the stray magnetic field acting in a direction opposite of B_{H}. This arrangement reduces the total magnetic field acting on the qubit 110, resulting in improved signal coherence.

The qubit 110 in FIG. 4a is at an initial (or equilibrium) position that is aligned with the center of the source of the stray magnetic field of B_{N}. This alignment means there would be no upward or downward component of B_{N} acting on the qubit 110 at this initial position. But displacing the qubit 110 relative to B_{N}, as shown in FIG. 4b, subjects the qubit 110 to the downward component of B_{N} on the right side of the qubit 110. Likewise, displacing the qubit to the left will subject the qubit 110 to the upward component of B_{N}.

FIGS. 4a and 4b illustrate tuning the magnetic field by electron dipole spin resonance (EDSR) or by baseband pulsing. EDSR involves applying an electric field on the gates 106 to displace the qubit 110 within a magnetic field gradient. If the displacement is oscillatory, and if the frequency of the oscillation matches the qubit's Larmor frequency, then EDSR drive is achieved. Due to the isotropic character of an electron tensor, the change of the Larmor vector is just related to the spatial change of the magnetic field. But the anisotropic g-tensor in Ge/SiGe holes leads to a quantization axis close to the z-axis direction for a magnetic field that lies mostly in the xy plane. The coherence time for Ge hole qubits increases inversely with the applied magnetic field due to the reduced sensitivity to charge noise. By displacing holes from their initial position, diabatic changes of the Larmor axis are possible that can be configured to provide spin rotations employed for single qubit baseband gates.

The electron hole spins 204 can be hosted in an anisotropic environment (given by the combination of the material and the electrical confinement) in which the vertical (out of plane or antiparallel) g-tensor value on the hole spins 204 is multiple orders of magnitude (100× or more) larger than the horizontal (in plane) g-tensor components. B_{H} is aligned parallel to the qubit plane (in plane direction) to define the qubit basis (left and right). B_{N} exists antiparallel to B_{H}, such as by fabricating the magnetic gates 106 of FIGS. 4a and 4b (also 5a and 5b) or by passing an electric current through a strip line in FIGS. 11a and 11b. In both cases, the direction of B_{N} varies from one place to another in the vicinity of the hole wave function 202 and will generally have both a horizontal and a vertical component.

For a single hole wave function 202 in a quantum dot, the hole wave function 202 can be shifted spatially by electric fields. For example, the hole wave function 202 for the qubit 110 can be controlled by varying a radio-frequency (RF) voltage V_{d} on the gate 106 to spatially displace the qubit 110 away from its initial position. Programmed tuning circuitry 402 can include a bias 404 controlling applications of analog RF signals V_{d} and digital gate signals V_{g}. EDSR requires a small B_{N} in comparison to the total magnetic field, with RF frequency applied to the qubit 110. The direction of the oscillation has to be perpendicular to the Larmor vector 206. If the oscillation frequency matches the Larmor frequency of the qubit 110, rotation between the two qubit states is achieved. These rotations are precessions around a new axis, such that a quantum gate which changes the qubit state between the two base states.

To achieve spin rotations by EDSR or baseband pulses, FIGS. 5a and 5b depict the peripheral manipulation circuitry 112 amplifying B_{N} by wavefunction displacement to perform qubit spin rotations in an array of single qubit gates. The peripheral manipulation circuitry 112 can modulate the qubit spin rotations to a desired frequency. Preferably, a baseband pulse signal has a lower frequency than the resonant frequencies of the qubits 110.

FIG. 5a illustrates each qubit 110 at its initial position. Barrier gates 504 can be formed between adjacent gates 106. Here, the hole spins 204 are polarized along the total magnetic field (B_{H}+B_{N}). B_{H} can be, for example, on the order of about 100 mT and pointing horizontally. B_{N} can be, for example, on the order of about 10 mT and also pointing horizontally in the location of the hole spin 204.

The baseband driving technique is based on hole spin precession. A magnetic moment precesses along the direction of the Larmor vector 206. If the total field is suddenly changed, the precession motion will change too. The amount of Larmor vector direction change is dependent on the g-tensor. For the hole spin qubits 110 in these illustrative embodiments, this change of Larmor vector direction can be very large even if the total field direction change is small.

FIG. 5b is similar to FIG. 5a but depicting a voltage Va has been applied to the gate 1062 to displace the qubit 110 from its initial position in FIG. 5a. This results in rapidly increasing the vertical component of B_{N} at the hole spin location. This small out-of-plane change in B_{N} (such as on the order of +5 mT) is amplified by the qubit's anisotropic g-tensor, such as on the order of a resulting in a 500 mT increase. This causes a large rotation of the Larmor vector 206 flipping its basis, such as vertically. Now the hole spin 204 (which still points left or right in this example) no longer points along the Larmor vector 206 and will therefore spin at a rapid speed not limited by B_{H}. This magnetic field manipulation by displacing the qubit 110 relative to B_{N} produces a gate time that is comparable to the inverse of the Larmor frequency (or resonant frequency) (t_{gate}=1/f) of a qubit, considerably faster than state-of-the-art EDSR manipulation. In this example, the qubit spin rotations are generated by applying baseband voltage pulses in a baseband signal to single qubit gates. A ramp time of the baseband signal is less than or equal to a precession period of the qubits in order to abruptly change the qubit precession axis. Thus, the manipulation circuitry 112 amplifies the magnetic field by using an antiparallel component of the nonhomogeneous field and the anisotropic g-tensor of each qubit.

In the case of EDSR, the anisotropy of the g-tensor enables a much smaller (such as 100× or smaller) displacement in comparison to a hypothetical isotropic g-tensor to achieve the same driving speeds as state-of-the-art manipulation times. Alternatively, if the same displacement distances are employed, up to about a 100× faster manipulation is possible.

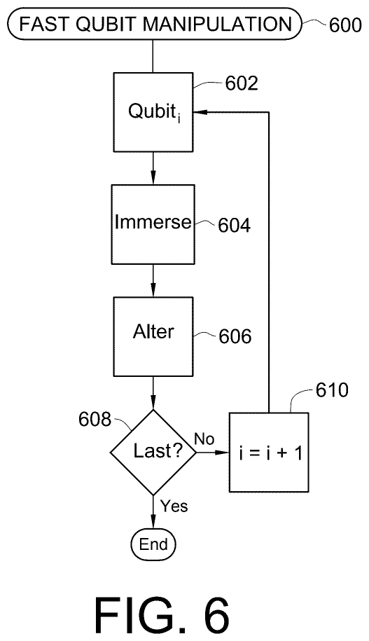

FIG. 6 is a flowchart depicting a method for fast qubit manipulation 600, consistent with illustrative embodiments. The method 600 can begin with block 602 forming a plurality of gates (such as 106) on a semiconductor substrate (such as 108) to produce an array of hole spin quantum dots (qubits, such as 110) in a qubit plane on the semiconductor substrate. Block 604 immerses the qubits in a magnetic field. The magnetic field can include a homogeneous field acting collectively on all the qubits in the array in a direction parallel to the qubit plane (such as B_{H}). The magnetic field can further include a nonhomogeneous field acting individually on each qubit in the array (such as B_{N}). Block 606 amplifies the nonhomogeneous field to perform qubit spin rotations in the array. In some embodiments, block 606 can amplify the nonhomogeneous field by applying an RF or baseband voltage to the gates (such as Va FIGS. 4a, 4b, 5a, 5b). In other embodiments, block 606 can amplify the nonhomogeneous field by applying alternating electric currents (such as FIGS. 11a, 11b).

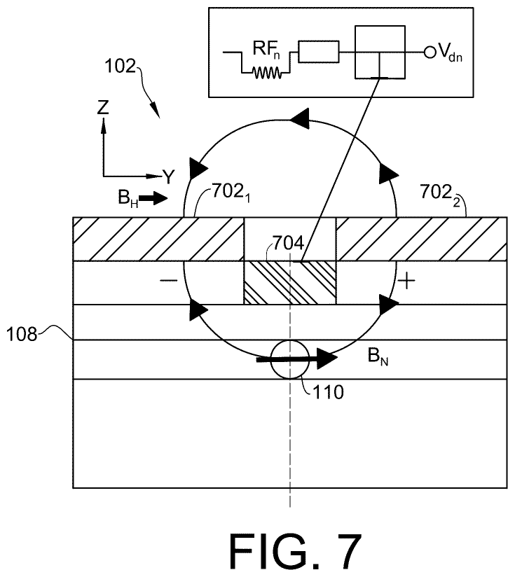

FIG. 7 depicts an alternative configuration of a two-piece magnetic structure 7021, 7022 overlying a gate 704. The two-piece magnetic structure 702 can be layered and etched on the semiconductor substrate 108. This configuration separates the quantum gate operations from the magnetic structure, allowing the gate 704 to be made of a nonmagnetic material. As before, the magnetic structure 702 is such that it is generally parallel to B_{H}. The magnetic field can be tuned individually for the qubit 110 by applying Va to displace the qubit 110 relative to B_{N} enough to manipulate the qubit spin.

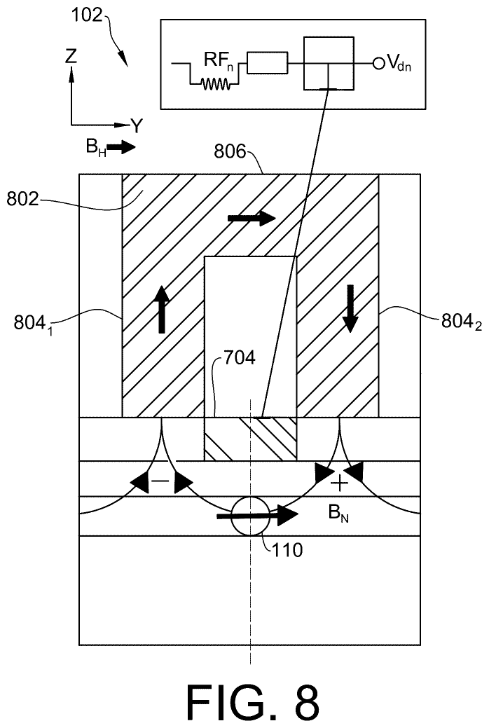

FIG. 8 depicts another alternative configuration of a horseshoe-shaped magnetic structure 802 overlying the nonmagnetic gate 704. The magnetic structure 802 can be layered and etched on the semiconductor substrate 108. In this way, the magnetic structure 802 can be about one micrometer long and can be located about 100 nanometers away from the qubit 110. As before, the magnetic structure 802 can such that it is parallel to B_{H}.

The magnetic structure 802 has a pair of protuberant poles 804 extending orthogonally to the qubit 110 and its qubit plane. A joint 806 extends parallel to the qubit plane (and thus parallel to B_{H}) and joins the pair of protuberant poles 804 together. The elongated form of the protuberant poles 804 enhances the shape anisotropy contribution, forcing the magnetization to orient essentially along the structure, and enhancing the stray-field at the qubit 110 locations. The size of each magnetic structure 802 can be about one micrometer or smaller.

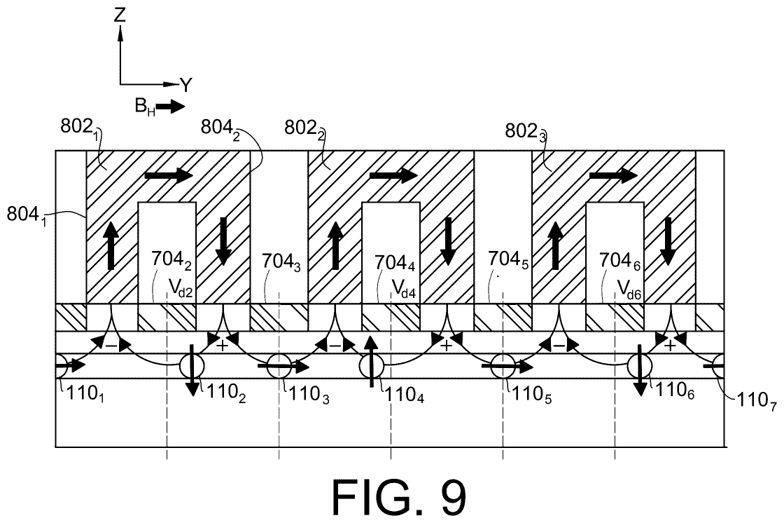

FIG. 9 depicts an elevational view of integrated circuitry architecture forming a one-dimensional array of qubits 110 with three of the horseshoe-shaped magnetic structures 802 in FIG. 8. Some of the qubits 110₂, 110₄, 110₆ are aligned between a pair of protuberant poles 804 in one of the magnetic structures 802. The other qubits 110₁, 110₃, 110₅, 110₇ are aligned between protuberant poles 804 of two adjacent magnetic structures 802. B_{N} can be a stray magnetic field extending between two of the protuberant poles 804, of the same or of two adjacent magnetic structures 802. Qubits 110₁, 110₃, 110₅, and 110₇ are depicted in initial positions. Qubits 110₂, 110₄, 110₆ are depicted in displaced positions, as a result of applying displacement voltages

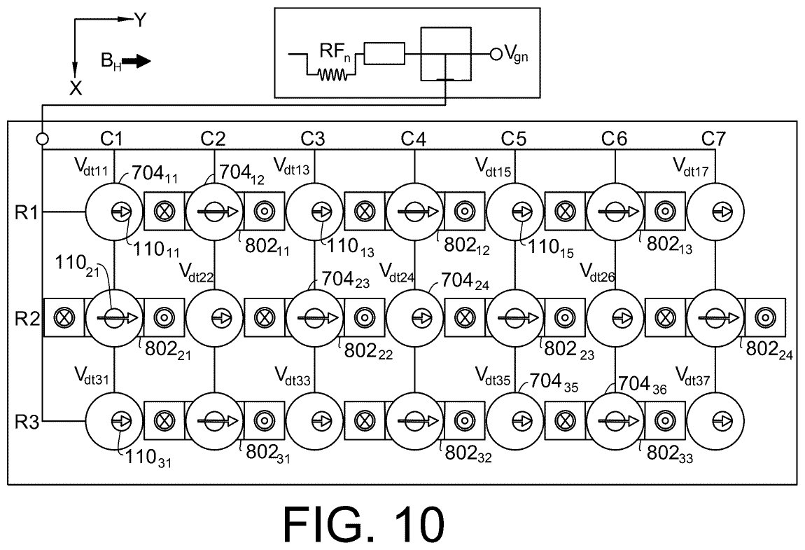

FIG. 10 depicts a bottom view of integrated circuitry architecture forming a two-dimensional array of qubits 110. A crossbar array is formed by a plurality of interconnecting rows and a plurality of columns. Each gate 704 is electrically connected at an intersection of a row control line Rm and a column control line Cn. Although FIG. 10 depicts each Rm and Cn as a single line for ease of illustration, one of skill in the art understands that each Rm and Cn can include multiple control lines interconnecting the gates 704. The peripheral manipulation circuitry 112 can likewise be interconnected to the gates 704 via the crossbar array. Other peripheral circuitries and data input/output circuitries can be interconnected with the gates 704 via the crossbar array for individually controlling each qubit 110 for such things as power, clock, bias, timing, and the like, to provide operable power distribution, control signals, clocking signals, and the like.

The top row R1 of this two-dimensional array includes seven qubits 110₁₁, 110₁₂, 110₁₃, 110₁₄, 110₁₅, 110₁₆, 110₁₇ in the same qubit plane. Four of those qubits 110₁₁, 110₁₃, 110₁₅, 110₁₇ are depicted being simultaneously displaced by application of respective voltages Vd₁₁, Vd₁₃, Vd₁₅, Vd₁₇. The middle row R2 is constructed similarly to R1 with seven qubits 110 in the qubit plane. It depicts simultaneously displacing three qubits 110₂₂, 110₂₄, 110₂₆ by application of respective voltages V_{d22}, V_{d24}, V_{d26}. The bottom row R3 is constructed and operated similarly to R1 with seven qubits in the qubit plane. It depicts the simultaneous displacing of four qubits 110₃₁, 110₃₃, 110₃₅, 110₃₇ by application of voltages V_{d31}, V_{d33}, V_{d35}, V_{d37}.

The magnetic structures 802 are configured to individually tune the magnetic field for each of one or more qubits 110. For example, magnetic structure 802₁₂ is configured to individually tune the magnetic field for qubits 110₁₃, 110₁₄, 110₁₅ in the first row of the qubit plane. Similarly, magnetic structure 802₂₂ is configured to individually tune the magnetic field for qubits 110₂₃, 110₂₄, 110₂₅ in the second row of the qubit plane.

FIG. 11a is similar to FIG. 5a in that again the peripheral manipulation circuitry 112 is amplifying B_{N} to perform qubit spin rotations in the array as single qubit gates generating baseband signals. Here though, the peripheral manipulation circuitry 112 can be programmed to amplify B_{N} by transmitting electric currents in strip lines 1102 to generate the nonhomogeneous field stray magnetic field components. In FIG. 11b, the electric currents are reversed in the strip lines 1102₂, 1102₃ to reverse direction of the corresponding Oersted fields. This aligns the adjacent stray magnetic fields acting on the second qubit 110₂, making the effect of amplifying B_{H} sufficient to flip the Larmor vector 206.

As in the baseband explanation for in FIGS. 4a and 4b, this baseband driving is based on Larmor precession. A magnetic moment precesses along a direction of the Larmor vector 206. If the total field direction is suddenly changed, the precession motion will change direction too. The amount of this direction change is dependent on the g-tensor. For hole spin qubits in these illustrative embodiments, this change of Larmor vector direction can be very large even if the total field direction change is small. For the illustrative embodiments of FIGS. 11a and 11b, if EDSR drive is performed, the oscillating field is directly achieved by sending an alternating current through the strip lines 1102.

So in these alternative illustrative embodiments, fast spin rotations are achieved by the peripheral manipulation circuitry 112 amplifying B_{N} by applying alternating electric currents to perform qubit spin rotations in an array of single qubit gates generating either a baseband or RF signal.

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings. The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

1. An apparatus comprising:
a semiconductor substrate;
a plurality of gates on the semiconductor substrate forming an array of hole spin quantum dots (qubits) at respective qubit positions in a qubit plane on the semiconductor substrate;
a magnetic field producing element configured to produce a total magnetic field, the magnetic field producing element comprising:
a homogeneous magnetic field producing element configured to produce a homogenous magnetic field acting collectively on all the qubits in the array in a direction parallel to the qubit plane; and
a nonhomogeneous magnetic field producing element configured to produce a nonhomogenous magnetic field acting individually on each qubit in the array,
wherein a frequency of each qubit depends on a direction of the total magnetic field; and
manipulation circuitry configured to perform qubit spin rotations in the array by amplifying the nonhomogeneous magnetic field in combination with anisotropic g-tensors of the qubits subjected to the total magnetic field.

2. The apparatus of claim 1, wherein the qubit spin rotations comprise single qubit gates generated with a baseband signal.

3. The apparatus of claim 2, wherein a ramp time of the baseband signal is less than or equal to a precession period of the qubits in the array operative to abruptly change a qubit precession axis.

4. The apparatus of claim 2, wherein a gate time for a rotation between two qubit states is related to an inverse of a resonant frequency of a qubit in the array.

5. The apparatus of claim 1, wherein the manipulation circuitry amplifies the nonhomogenous magnetic field by spatially displacing the qubits relative to the total magnetic field.

6. The apparatus of claim 5, wherein the manipulation circuitry applies radio-frequency voltages to the plurality of gates.

7. The apparatus of claim 1, wherein the nonhomogenous magnetic field comprises a plurality of magnetic structures each configured parallel to the homogeneous magnetic field.

8. The apparatus of claim 7, wherein the plurality of magnetic structures comprises a deposited layer on the semiconductor substrate.

9. The apparatus of claim 7, wherein each of the plurality of magnetic structures has a stray magnetic field extending from one end of each magnetic structure to an opposing end of each magnetic structure.

10. The apparatus of claim 9, wherein each stray magnetic field subjects a corresponding qubit to:
a first stray magnetic field component in a direction of the homogeneous magnetic field; and
a second stray magnetic field component in a direction antiparallel to the homogeneous magnetic field.

11. The apparatus of claim 9, wherein each magnetic structure comprises:
a pair of protuberant poles extending orthogonally to the qubit plane; and
a joint extending parallel to the qubit plane and joining the pair of protuberant poles together,
wherein the joint is aligned parallel to the homogeneous magnetic field.

12. The apparatus of claim 11, wherein at least one of the qubits is aligned between one of the pair of protuberant poles in one of the magnetic structures.

13. The apparatus of claim 11, wherein at least one of the qubits is aligned between the protuberant poles of two adjacent magnetic structures.

14. The apparatus of claim 1 wherein the qubit plane is formed by a two-dimensional array of the qubits.

15. The apparatus of claim 10, wherein the manipulation circuitry amplifies the nonhomogenous magnetic field by using the second stray magnetic field component.

16. The apparatus of claim 1, wherein the manipulation circuitry amplifies the nonhomogeneous magnetic field by generating alternating electric currents.

17. A method, comprising:
forming a plurality of gates on a semiconductor substrate to produce an array of hole spin quantum dots (qubits) at individual qubit positions in a qubit plane on the semiconductor substrate;
subjecting the qubits to a magnetic field producing element configured to produce a total magnetic field, the magnetic field producing element comprising:
a homogeneous magnetic field producing element configured to produce a homogenous magnetic field acting collectively on all the qubits in the array in a direction parallel to the qubit plane; and
a nonhomogeneous magnetic field producing element configured to produce a nonhomogenous magnetic field acting individually on each qubit in the array,
wherein a frequency of each qubit depends on a direction of the total magnetic field; and
amplifying the nonhomogeneous magnetic field at the individual qubit positions to perform qubit spin rotations in the array.

18. The method of claim 17, wherein the amplifying comprises applying a baseband signal to one or more of the plurality of gates.

19. The method of claim 17, wherein the amplifying comprises generating alternating electric currents.

20. A quantum computing system having reduced manipulation time, the system configured to perform a method, comprising:
forming a plurality of gates on a semiconductor substrate to produce an array of hole spin quantum dots (qubits) at individual qubit positions in a qubit plane on the semiconductor substrate;
subjecting the qubits to a magnetic field producing element configured to produce a total magnetic field, the magnetic field producing element comprising:
a homogeneous magnetic field producing element configured to produce a homogenous magnetic field acting collectively on all the qubits in the array in a direction parallel to the qubit plane; and
a nonhomogeneous magnetic field producing element configured to produce a nonhomogenous magnetic field acting individually on each qubit in the array,
wherein a frequency of each qubit depends on a direction of the total magnetic field; and
amplifying the nonhomogeneous magnetic field at the individual qubit positions to perform qubit spin rotations in the array.
